(19) United States
(12) Patent Application Publication
(10) Pub. No.: US 2023/0162062 A1
(43) Pub. Date: May 25, 2023

(54) OPTIMIZATION AND DECISION-MAKING USING CAUSAL AWARE MACHINE LEARNING MODELS TRAINED FROM SIMULATORS

(71) Applicant: MICROSOFT TECHNOLOGY LICENSING, LLC, Redmond, WA (US)

(72) Inventors: Emre Mehmet KICIMAN, Seattle, WA (US); Qie ZHANG, Houston, TX (US); Cheng ZHANG, Cambridge (GB); Swati SHARMA, Hayward, CA (US); Yuhao DING, Albany, CA (US); Ranveer CHANDRA, Kirkland, WA (US)

(21) Appl. No.: 17/531,700

(22) Filed: Nov. 19, 2021

(51) Int. Cl. G06N 5/04; G06K 9/62; G06N 20/00

(52) U.S. Cl. CPC G06N 5/042; G06K 9/6256; G06K 9/6262; G06N 20/00

(57) ABSTRACT

Techniques are described herein for reducing the computing cost of decision-making when simulating a real-world system. A machine learning model is trained using data generated by a simulator of the real-world system. Knowledge about how the simulator is implemented is used to improve the efficiency of the machine learning model and to improve the relevance of data selected to train the machine learning model. For example, structural knowledge—the flow of input variables through components of the simulator—is used to determine a causal relationship between input variables. Having identified the causal relationship, the number of simulator iterations used to generate training data may be reduced. Furthermore, large complex machine learning models may be replaced with smaller, more efficient models. Additionally, or alternatively, causal relationships between input variables are identified during training, enabling further refinement of input selection and model design.

### BACKGROUND

Computer simulations of real physical systems are used in a variety of industries to drive decision making. Simulator software uses equations, numerical methods, rules, and other techniques to model a real-world system. For example, a physics-based simulator may be used predict how a real-world system would react to various configurations, usage patterns, operating environments, and other parameters. These parameters are collectively referred to as inputs variables, while the predictions made by the simulator are referred to as output variables.

Modeling a system by computer simulation can save time and money compared to building a real physical system. For example, the aerodynamics of automobiles may be estimated by computer simulation in less time and for less expense than building a physical model and testing it in a wind tunnel. Supply chains, power grids, computer networks, queuing systems, and circuit layouts are other examples of systems that may be simulated to evaluate a most likely outcome for a particular design, policy, or other input.

While physics-based simulators often yield results sooner and more efficiently than constructing and testing a real physical system, they still require significant computing resources and can take hours or even days to complete. For example, one iteration of a simulator may consume 100 cloud compute instances for 8 hours. One hour of a single cloud compute instance may cost 10 cents and consume 100 Watts of electricity. As such, a single iteration of the simulator may cost $80 and consume 80,000 Watts of electricity. These costs are particularly limiting when running the simulator multiple times, e.g. to search for an optimal set of inputs. For example, evaluating 10,000 possible combinations of inputs would cost $800,000 and consume 800 million Watts of electricity.

When the number of inputs is large, running a simulator for each permutation becomes intractable. For example, a model with 150 binary inputs would have to be simulated 10⁴⁵ times to evaluate each permutation. Techniques such as genetic algorithms, simulated annealing, random search, factorial designs, and response-surface methodology may reduce the number of iterations needed to identify an optimal set of inputs, but the time and expense may still be unacceptably high. In addition to searching for an optimal set of inputs, a simulator may also be used to augment human decision-making by enabling a human decision maker to “double check” particular sets of inputs. Even in this context, executing the simulator multiple times may be costly, time consuming, and environmentally intensive.

Given the growing number of applications and industries that use simulators to plan complex systems, there is a growing need to improve the efficiency of decision making using simulations. The disclosure made herein is presented with respect to these and other considerations.

### SUMMARY

Techniques are described herein for reducing the computing costs and time spent evaluating configurations of a real-world system. Computing costs are reduced by using a machine learning model to make predictions about the real-world system, which requires less time and fewer computing resources than a traditional simulator. This reduction in time and expense enables designers to quickly evaluate different configurations of the real-world system.

In some embodiments, the machine learning model is trained with data generated by a simulator that evaluates configurations of the real-world system. Each configuration is defined by a set of input variables, and the results of the simulation are represented by one or more output variables. These inputs and outputs are used to train the machine learning model. In this way, the machine learning model will approximate the simulator, and so the machine learning model can itself be used to evaluate configurations of the real-world system.

Knowledge about how the simulator is implemented—referred to herein as domain knowledge—may be used to improve the efficiency of the machine learning model and to improve the relevance of data selected to train the machine learning model. While discussed below in further detail, one type of domain knowledge is knowledge of the internal structure of the simulator—the flow of input variables through components of the simulator. This structural knowledge may be used to identify a causal relationship between a set of input variables, e.g. that the set of input variables are non-interacting. Two input variables are non-interacting when an effect of one variable on output variables is independent of the other variable. For example, in a power grid simulator that yields an amount of carbon dioxide (CO₂) emissions, an input variable representing average monthly temperature is non-interacting with an input variable representing population growth rates if average monthly temperature does not affect how population growth impacts CO₂ emissions.

In some configurations, structural knowledge may be used to determine that two input variables are non-interacting based on a determination that each input variable is processed by different, non-overlapping paths through the simulator. When input variables are processed by non-overlapping paths, the value of one input variable has no way of interacting with the value of the other input variable, and so neither input variable changes how the other affects simulator output. For example, an input variable representing average monthly temperature may be processed by a weather forecasting component of the simulator, while a population growth rate input variable may be processed by a population growth prediction component of the simulator. If the outputs of these components are not used as inputs to a shared component—directly or indirectly—then the average monthly temperature input variable and the population growth rate input variable are determined to be non-interacting.

Determining that two input variables are non-interacting may reduce the amount of processing needed to train the machine learning model. For example, if variables A and B are both inputs to a simulator that yields output Z, and A and B are non-interacting, then the value of B does not impact how A affects Z. As such, the effect of A on Z may be measured by adjusting the value of A across multiple simulations while holding the value of B constant. In this way, the number of simulations needed to evaluate the impact of A on Z grows linearly with the number of possible values of A. Similarly, the impact of B on Z may be measured by varying the value of B across multiple simulations while holding the value of A constant. Together, the number of simulations required equals the number of possible values of A plus the number of possible values of B.

However, if A and B interact with one another to produce Z, then understanding the relationship between A and Z would require training data that varies B in addition to varying A. In this scenario, the number of simulations would be approximately the number of possible values of A multiplied by the number of possible values of B. This is significantly more than if B were held constant. If Z depended on a third input variable C that is also non-interacting with A and B, then the number of simulations needed would be approximately the product of the number of possible values of each of A, B, and C.

As such, an observation from domain knowledge that input variables are non-interacting may be used to reduce the number of simulator iterations needed to generate sufficient training data. Additionally, or alternatively, simulator iterations may be reallocated from redundant combinations of non-interacting variables to refining the simulation of other inputs, expanding the number of inputs, or otherwise improving the accuracy of the machine learning model.

The observation that a set of variables are non-interacting may also be used to design a more efficient machine learning model. For example, if two input variables are determined to be non-interacting, a machine learning model trained on both variables could be replaced with two machine learning models that are each trained with a single input variable. Since machine learning models are trained on a representative sample of combinations of input variables, the complexity of the model may grow geometrically with the number of input variables. Replacing a model that has two input variables with two single-variable models can therefore reduce the cost of training by a factor of two. Replacing a three-input model with three single input models may reduce the cost of training by a factor of three, etc.

In some configurations, causal relationships between input variables may be identified in real-time while training the machine learning model. For example, causal discovery algorithms may determine that two input variables are non-interacting. Once this relationship is established, redundant training data—e.g. training data in which one of the non-interacting variables is not held constant—may be omitted or replaced as discussed above. Furthermore, once this relationship is established, single machine learning models that train on multiple input variables may be replaced by multiple machine learning models that each train on fewer input variables, as discussed above.

One benefit of simulating the real-world system with a machine learning model trained with simulator generated data is the ability to refine the machine learning model based on real-world data. In this context, real-world data refers to data about the real-world system that the simulator is not programmed to consider, but which may have an effect on the system. For example, real-world data may be used to calibrate the machine-learning model to a local environment. Real-world data may also be used as a stand-in for the effects of minor processes or mechanisms that are not incorporated in the simulator. Back-propagation and other training techniques may be used to incorporate this additional knowledge into the machine learning model. Simulators, in contrast, may not allow tweaking or other adjustments that would allow this type of information to be incorporated.

Another benefit of simulating the real-world system with a machine learning model trained with simulator generated data is that the model may be optimized for a desired output using a model inversion technique. This technique works backwards from the desired output to determine a set of inputs that will cause the model to yield the desired output. For example, layers in the trained model may be analyzed iteratively from the final layer to the first layer. At each layer, a gradient descent technique may be applied to minimize a loss function for the desired output. This technique is applied to each layer until a set of input values is inferred that will yield the desired output. In this way, a set of inputs can be identified that optimize the real-world system without exhaustively running a simulation for all or even most of the possible input permutations.

There are many other advantages to the disclosed techniques. Computing costs are reduced because the number of simulator iterations needed to generate sufficient training data is reduced. Accuracy of the machine learning model is increased by selecting simulator inputs that improve the quality of the resulting training data. Using the trained machine learning model to simulate a given set of inputs is faster and cheaper than running a simulator, enabling quick and agile experimentation with different input values.

A power grid simulator is one example of a simulator that may be used to train a machine learning model. The power grid simulator may be run multiple times with different input variables defining power plant capacity, transmission line layouts, environmental baselines, etc. The power grid simulator may predict an amount of carbon emitted by power generation for a given set of inputs. The sets of inputs and their corresponding outputs may then be used to train a machine learning model that approximates the simulator.

In some configurations, domain knowledge such as structural knowledge about the implementation of the power grid simulator may be used to infer a causal relationship between input variables. The causal relationship may then be used to refine the machine learning model. For example, an electricity demand simulator component may output a value to a power generation simulator component, which outputs a value to a power transmission component. Instead of training a single machine learning model on all of the inputs and outputs provided to these components, domain knowledge may be used to train individual models for the electricity demand component, the power generation component, and the power transmission component. The time and expense required to train the three separate models, including their interactions with each other, will be less than training a single model on all three input variables.

It should be appreciated that the above-described subject matter may also be implemented as part of an apparatus, system, or as part of an article of manufacture. These and various other features will be apparent from a reading of the following Detailed Description and a review of the associated drawings.

This Summary is provided to introduce a selection of concepts in a simplified form that are further described below in the Detailed Description. This Summary is not intended to identify key features or essential features of the claimed subject matter, nor is it intended that this Summary be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

The Detailed Description is described with reference to the accompanying figures. References made to individual items of a plurality of items can use a reference number with a letter of a sequence of letters to refer to each individual item. Generic references to the items may use the specific reference number without the sequence of letters.

FIG. 1A shows a box diagram of a simulator simulating a real-world system.

FIG. 1B shows a box diagram of designing a machine learning model with domain knowledge about the simulator.

FIG. 1C shows a box diagram of selectively choosing simulation inputs with which to train a machine learning model.

FIG. 2A shows a box diagram of providing input variable values to a machine learning model to simulate a real-world system.

FIG. 2B shows a box diagram of multiple machine learning models approximating a simulator with multiple components.

FIG. 3 shows a box diagram of applying an inversion optimization to one or more desired output variable values to generate a set of input variable values that yields the desired outputs.

FIG. 4A shows a graph of raw predicted values generated by a machine learning model trained to approximate a simulator of a real-world system.

FIG. 4B shows a graph of smoothed predicted values generated by a machine learning model trained to approximate a simulator of a real-world system.

FIG. 5 shows a box diagram of a multi-step simulator that is used to train multiple machine learning models.

FIG. 6 is a flow diagram illustrating an example operational procedure according to the described implementations.

FIG. 7 is a computer architecture diagram illustrating a computing device architecture for a computing device capable of implementing aspects of the techniques and technologies presented herein.

### DETAILED DESCRIPTION

In the following detailed description, reference is made to the accompanied drawings, which form a part hereof, and which is shown by way of illustration, specific example configurations of which the concepts can be practiced. These configurations are described in sufficient detail to enable those skilled in the art to practice the techniques disclosed herein, and it is to be understood that other configurations can be utilized, and other changes may be made, without departing from the spirit or scope of the presented concepts. The following detailed description is, therefore, not to be taken in a limiting sense, and the scope of the presented concepts is defined only by the appended claims.

Throughout the specification and claims, the following terms take the meanings explicitly associated herein, unless the context clearly dictates otherwise. The meaning of “a,” “an,” and “the” includes plural reference, the meaning of “in” includes “in” and “on.”

The presently disclosed techniques may be employed to provide for efficient simulation of a real-world system. An additional benefit is enabling effective inversion of a simulator that is not directly invertible.

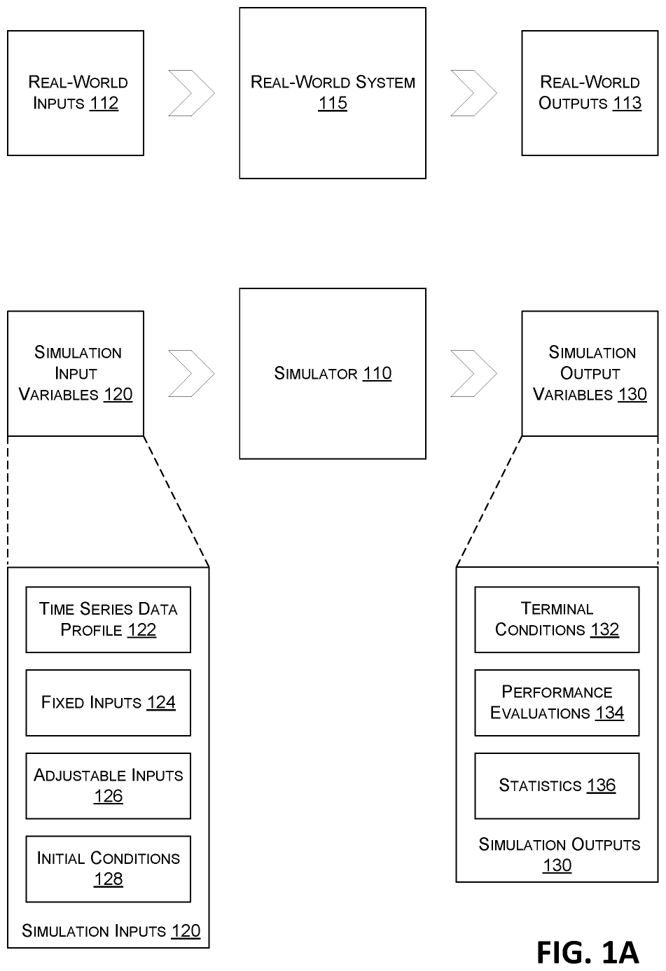

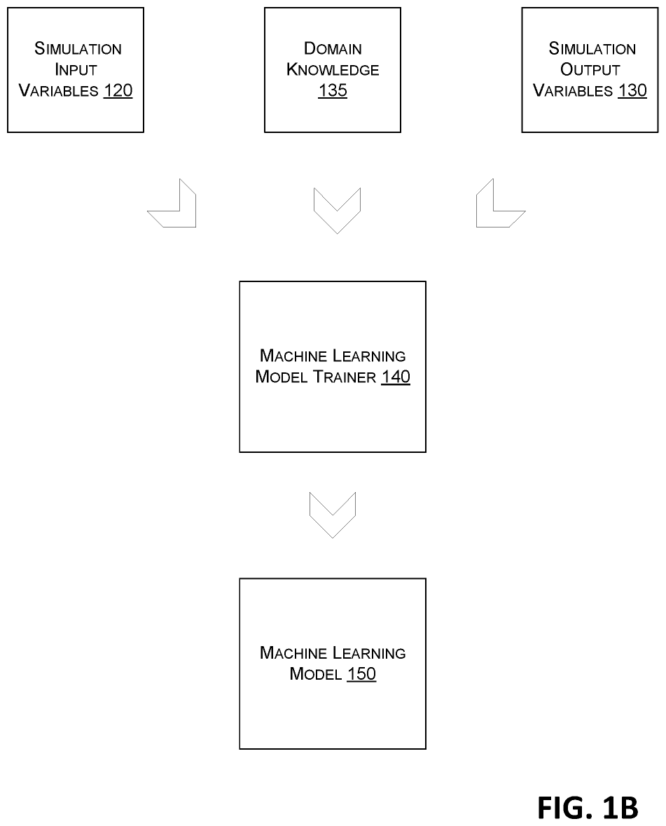

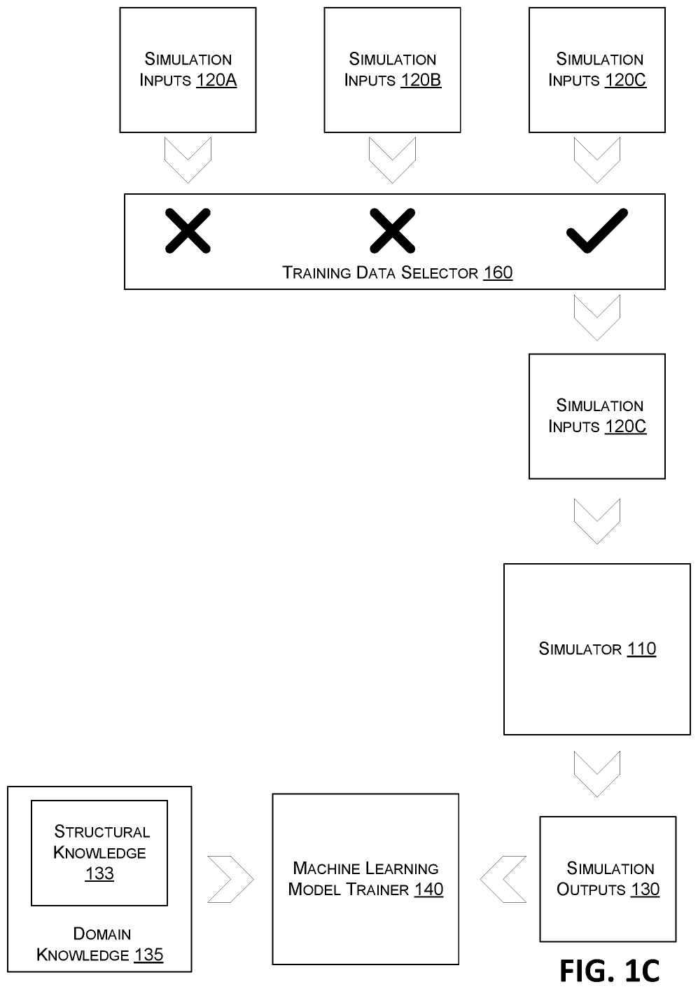

FIG. 1A shows a box diagram of a simulator 110 simulating a real-world system 115. Real-world system 115 may be any physical or logical system that is complex enough to make modeling worthwhile. Examples include power grids, digital circuits, supply chains, airline schedules, traffic patterns, financial systems, etc. Real-world system 115 may be modeled in anticipation of being built, modified, decommissioned, or otherwise altered. Real-world system 115 may also be modeled in order to best utilize the existing system as-is. Real-world system 115 may often be modeled to predict an effect, outcome, or other consequences of configuring real-world system 115 in a particular way. As illustrated, real-world inputs 112 represent the ways in which real-world system 115 could be configured. For example, when modeling an airline schedule, real-world inputs 112 may represent jet fuel prices, current demand, turn-around time, and other factors affecting airline schedules. Real-world outputs 113 represents the predicted effects, outcomes, or other consequences of configuring real-world system 115 according to real-world inputs 112.

Simulator 110 may simulate real-world system 115. As such, simulator 110 may include simulation input variables 120 that represent real-world inputs 112 and simulation output variable values 130 that represent real-world outputs 113. Simulator 110 may be built with one or more of a combination of differential equations, linear equations, rules, statistical computations, state machines, or the like. These aspects of simulator 110 are employed to model real-world system 115 according to the values of simulation input variables 120 in order to yield output variable values. As referred to herein, an input variable represents the variable symbolically, while an input variable value represents a particular value of an input variable.

Simulation input variables 120 may include time series data profile 122, fixed inputs 124, adjustable inputs 126, initial conditions 128, and the like. Time series data profile 122 may represent data that occurs over a period of time, such as weather data, sunlight data, traffic patterns, and like. Fixed inputs 124 represent states of the world that cannot change, such as the number of hours in a day, or the direction of the prevailing wind. Fixed inputs 124 may also represent inputs to simulator 110 that are held constant in order to isolate the operation of other inputs. Adjustable inputs 126 represent inputs that may be changed in order to optimize one or more simulation output variables 130. For example, a power grid simulation may assume in some circumstances that the layout of transmission lines is fixed, in which case a description of the layout and capacity of transmission lines would be included in fixed inputs 124. However, if the layout of transmission lines in a power grid is an independent variable being explored, it could be one of adjustable inputs 126. Initial conditions 128 may represent parameters that have an initial value, but that are expected to be updated during the simulation. For example, electricity demand may have an initial condition 128, the demand for electricity is expected to change overtime as the simulator progresses.

Simulation output variables 130 include terminal conditions 132, performance evaluations 134, statistics 136, etc. Terminal conditions 132 refer to outputs of simulator 110 that describe the state of real-world system 115. For example, a simulator that models land use may provide as a terminal condition 132 an amount of land predicted to be dedicated to housing, farming, nature, etc. Performance evaluations 134 represent a utilization of an asset of real-world system 115 as modeled by simulator 110. For example, in a power grid simulator, a performance evaluation 134 of a transmission line may indicate how much the line was used, expected maintenance costs, etc. Statistics 136 represents aggregate statistical results across the simulation. For a power grid simulation, statistics 136 may include average utilization per home, amount of energy curtailment for each source of energy, and the like.

Simulating real-world system 115 with simulator 110 may take less time and require fewer computing resources than building a real-world model of real-world system 115, but simulator 110 may still be computationally expensive, taking minutes, hours, or days to execute, even on a large computing cluster.

FIG. 1B shows a box diagram of designing a machine learning model 150 based on domain knowledge 135. Domain knowledge 135 may include structural knowledge about simulator 110. Structural knowledge may include information about which components simulator 110 is made of, how components of simulator 110 yield intermediate variables, and which input variables are processed by which components as data passes through machine learning model 150. If input variables do not cross paths throughout the simulator, machine learning model trainer 140 may infer that the input variables are non-interacting—i.e. the value of one variable is independent of how another independent variable affects an output variable value. In some configurations, machine learning model trainer 140 is also provided with simulation input variables 120 and simulation output variables 130 for use in constructing machine learning model 150.

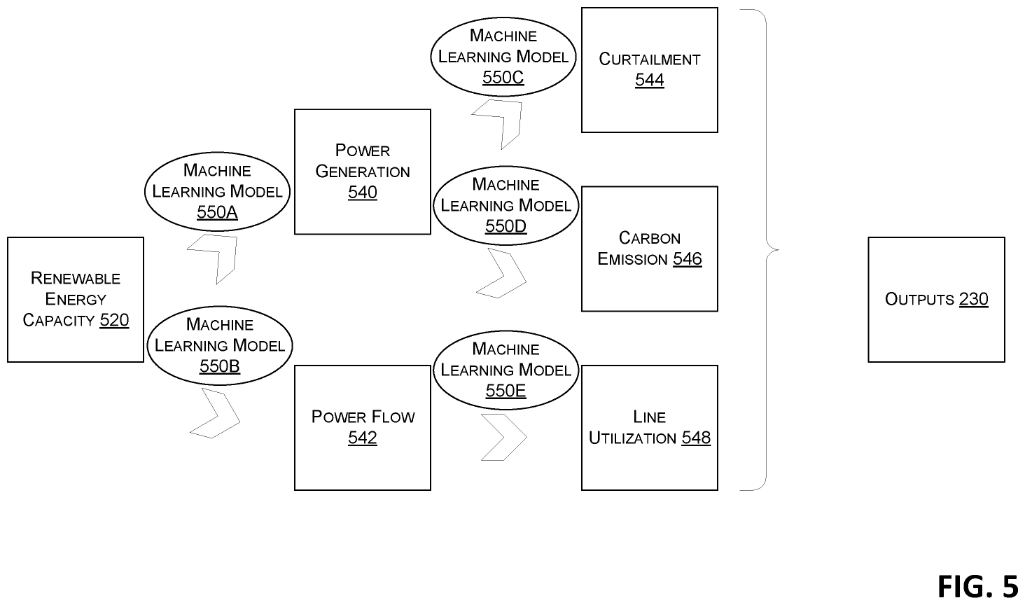

Machine learning model 150 may initially be designed to process simulation input variable values with a single machine learning model. However, as discussed in more detail below in conjunction with FIG. 5, smaller, individual machine learning models may replace the single machine learning model based on domain knowledge 135. Specifically, if two input variables 120 are known to be independent based on domain knowledge 135, then a machine learning model that processes both inputs may be replaced with two smaller machine learning models, each of which processes a single input.

FIG. 1C shows a box diagram of selectively choosing simulation input variables 120 with which to train a machine learning model 150. Under some circumstances, the machine learning model generated from simulation inputs 120 and corresponding outputs 130 is prone to identifying spurious associations. When this happens, machine learning model 150 is more likely to generate incorrect predictions, particularly for inputs that stray from the region of simulation inputs 120.

In order to limit the identification of patterns that do not reflect the mechanisms governing real-world system 115, training data selector 160 may strategically select or reject simulation inputs 120 to be simulated. The selected inputs 120C are provided to simulator 110, which yields simulation outputs 130. The selected inputs 120C and their corresponding simulation outputs 130 may then be used by machine learning model trainer 140 to train machine learning model 150. As illustrated, simulation inputs 120A and 120B are not selected by training data selector 160.

In some configurations, training data selector 160 is part of machine learning model trainer 140. When there is no structural knowledge 133 about the internal mechanisms of simulator 110, training data selector 160 may resort to randomly selecting simulation inputs 120. However, when machine learning model trainer 140 does have structural knowledge 133 about simulator 110, causal discovery algorithms may be used to ensure that multiple input variables are not entangled, obscuring the causes of patterns and trends. Domain knowledge 131 may also be used by machine learning model trainer 140. For example, domain knowledge about a maximum amount of power emitted by a particular type of power plant may be encoded in domain knowledge 131. Other types of domain knowledge 131 may prevent the model from learning a spurious correlation. Machine learning model trainer 140 may use this knowledge to further limit the data selected from simulator 110 used to train machine learning model 150.

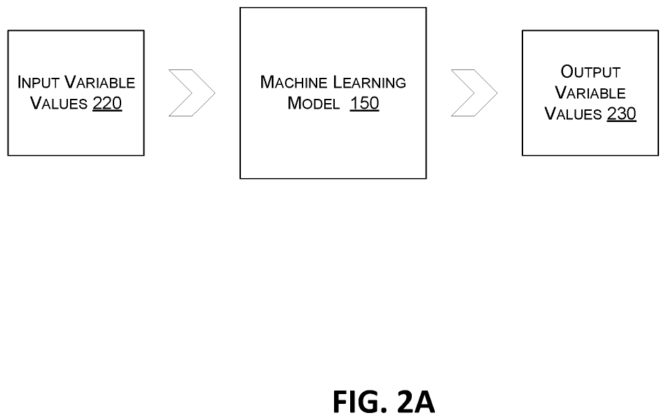

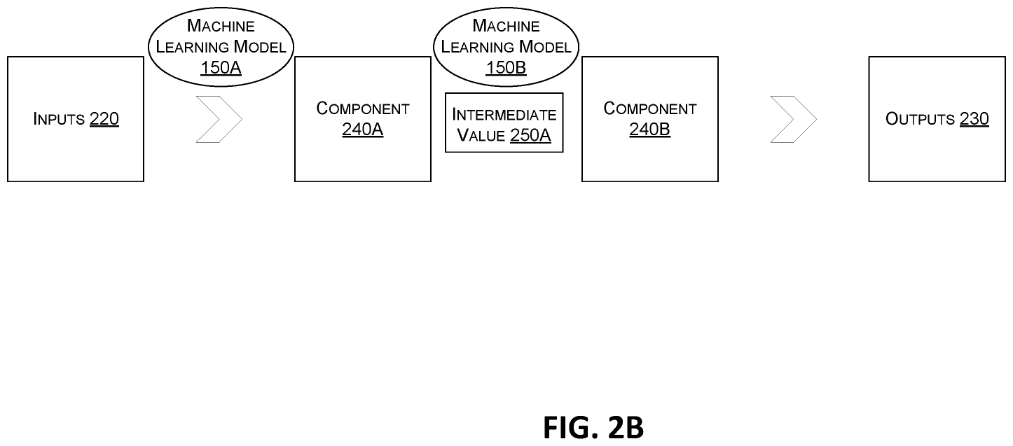

FIG. 2A shows a box diagram of providing input variable values 220 to a machine learning model 150 to simulate a real-world system 115. In some configurations, FIG. 2A illustrates one way in which machine learning model 150 is utilized to approximate the outputs of simulator 110, and thereby predict outcomes of real-world system 115. Specifically, FIG. 2A illustrates a forward application of machine learning model 150 to inputs 220, yielding outputs 230. In this way, a user may utilize machine learning model 150 to make a prediction about how real-world system 115 will operate given a particular set of inputs 220.

FIG. 2B shows a box diagram of multiple machine learning models 150 approximating a simulator 110 with multiple components 240. Some simulators 110 are black boxes, accepting simulator inputs 220 and yielding simulator outputs 230, without providing any knowledge of how the prediction is made. These simulators may be approximated with a single, end-to-end machine learning model 150. Other simulators 110 utilize multiple components 240 or other subsystems in order to approximate real-world system 115. For these simulators 110, components 240 may produce intermediate variables that are supplied to one or more other components 240, or components 240 may produce a final output 230. Each component 240 may be used to train a different machine learning model 150—the inputs and outputs of a particular component 240 are used to train a corresponding machine learning model 150. For a power grid simulation, one example of an intermediate variable is line utilization—e.g. that a transmission line from Dallas to Houston is 80% used. An intermediate variable establishes structure—e.g. the output of one model 150 is input to another.

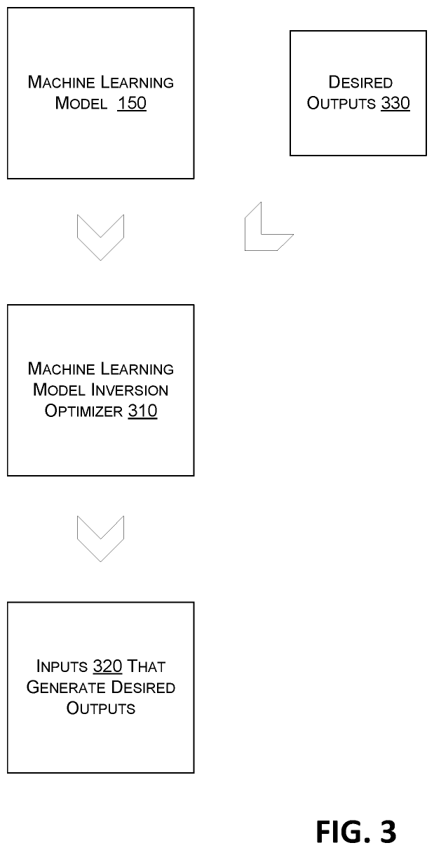

FIG. 3 shows a box diagram of applying an inversion optimization to one or more desired outputs 330 to generate a set of inputs 320 that yields the desired outputs 330. Machine learning model inversion optimizer 310 may begin with desired output 330 and apply a gradient descent algorithm to determine the weights at each layer of machine learning model 150. The final layer of weights—those that yield the output of the machine learning model, are iteratively adjusted until they yield the desired output 330. The weights of the previous layer are similarly identified, and this process continues until the input values 320 that yield desired outputs 330 are found.

At each layer, the gradient descent technique may compute a slope of the loss function. The slope may be computed by differentiating the loss function or by approximating a slope. Machine learning models are designed so that the loss functions will be differentiable or otherwise usable to compute a slope. In contrast, simulator 110 may be constructed out of any type of function, or no function at all, and as such is not always invertible or differentiable.

The gradient descent approach may also be beneficial when equations are differentiable but that are too difficult to mathematically invert, or for equations that may be inverted but for which solving the inverted equation is too computationally expensive.

For example, during the inversion optimization process for minimizing an output value, weights are identified for the final layer of the machine learning model by randomly selecting an initial value, determining the gradient (slope) of the output function at that point, and selecting a new value based on the sign of the gradient. If the sign is negative, the new value is selected to be greater than the previous value, and if the sign is positive, the new value is selected to be less than the previous value. In this way, the weight will converge so as to minimize the output value. Differentiability and other techniques described herein for computing a slope enable converging on a minimum (or maximum value) of the inverted function.

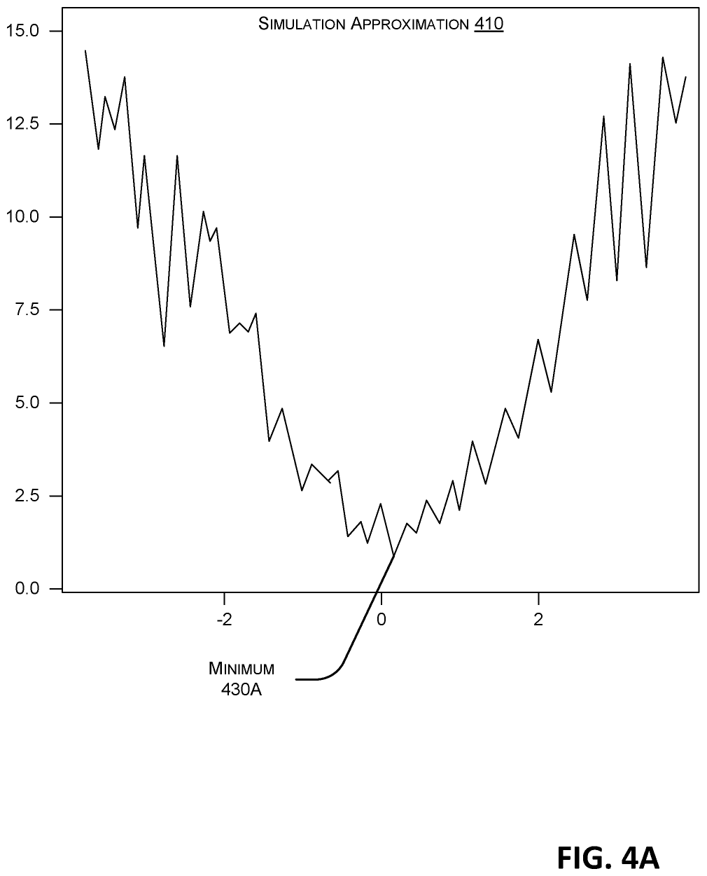

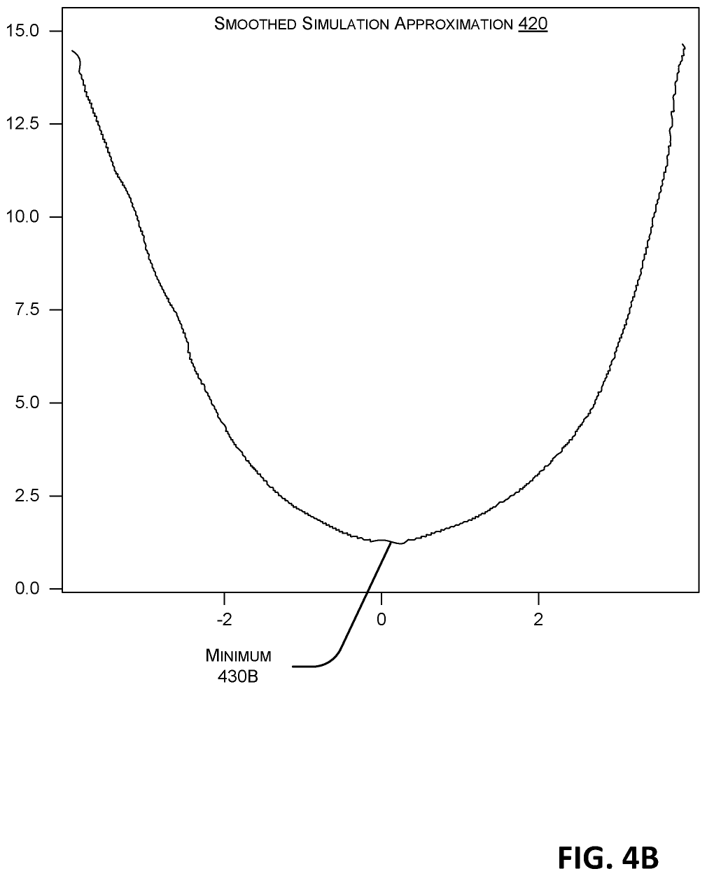

FIG. 4A shows a graph 410 of raw predicted values generated by a machine learning model 150 trained to approximate a simulator 110 of a real-world system 115. As illustrated, there is not a smooth slope with which to converge on a minimum value 430A, but jagged irregular slopes that would not converge quickly or at all to the global minimum. In some embodiments, the jagged nature of the predicted values can be overcome by sampling multiple points and averaging the gradients of each point. this has the effect of capturing a general trend in the gradient, smoothing out the effect of a few errant points. Additionally, or alternatively, the jagged nature of the predicted values can be overcome by smoothing out training data before it is used to train machine learning model 150.

FIG. 4B shows a graph of smoothed predicted values 420 generated by a machine learning model 150 trained to approximate a simulator 110 of a real-world system 115. FIG. 4B illustrates a result of applying smoothing techniques to the raw predicted values illustrated in FIG. 4A, identifying minimum 430B. One technique for smoothing the predicted values is to sample a number of values that are adjacent or near adjacent to each other and average the values. Similar to sampling multiple gradients and averaging their values, averaging the values themselves has the effect of smoothing out a few errant points. Once the predicted values have been smoothed, the gradient descent algorithm becomes more efficient and more accurate, as there is less of a tendency to encounter gradients that direct away from the optimal value.

FIG. 5 shows a box diagram of a multi-component simulator that is used to train multiple machine learning models 550. In some configurations, every component is trained with a corresponding machine learning model. Alternatively, a single machine learning model could be trained by enforcing statistical independence between unrelated components. For example, a statistical independence could be enforced that filters out all data from simulator 110 that suggests a correlation between carbon emission 546 and line utilization 548, which as illustrated, do not depend directly on one-another.

FIG. 5 Illustrates a multi-component simulator that predicts outputs 230 of a power grid. Capacity 520 represents inputs that affect the amount of renewable energy that is generated. Capacity parameters 520 are used to train machine learning models 550A and 550B and are provided to power generation component 540 and power flow component 542. In this example, capacity 520 represents renewable energy capacity, power generation 540 represents baseload power generation capacity, and power flow 542 represents a measure of power as it leaves one of the renewable energy plants represented by capacity 520. Machine learning models 550A and 550B also are trained with output parameters yielded by power generation component 540 and power flow component 542, respectively.

In this example, only capacities of renewable energy plants are inputs—all other aspects about the structure of the power grid are internal to simulator 110. As such, before this model could be applied to a different power grid, a different simulator 110 would need to be developed. However, in other embodiments, additional input values may be used to parameterize other aspects of the power grid.

Similarly, machine learning model 550C is trained with the inputs to curtailment component 544—e.g. the output of power generation component 540—and the output of curtailment component 544 itself. Machine learning model 550D is trained with the inputs to carbon emissions component 546 and the output of carbon emission component 546 itself. And machine learning model 550E is trained with the inputs to line utilization component 548 in addition to the outputs yielded by line utilization component 548.

Training a distinct machine learning model for each step of simulator 110 enables domain knowledge such as intermediate data and structural knowledge to constrain the training of machine learning model 150. When utilizing different machine learning models for different components of simulator 110, gradient descent may still be used to identify a set of input parameters that yield a desired output value, just as with a single machine learning model. However, the technique is expanded to work backwards from the desired output to the desired input of each machine learning model that contributes directly to the outputs 230—e.g. machine learning models 550A-C, which model curtailment component 544, carbon emission component 546, and line utilization component 548 are associated with, respectively. The input values of these models are then provided as the outputs of the preceding models, e.g. machine learning models 550A and 550B, and the process repeats. Eventually, the machine learning models that approximate the first steps of simulator 110 are inverted to optimize the input parameters, e.g. renewable energy capacity 520.

In some configurations, domain knowledge 135 is inferred from a simulator consisting of multiple components, as illustrated in FIG. 5. Structural knowledge about the simulator may indicate that input variables of power generation component 540 are non-interacting with input variables of power flow component 542. Specifically, a path through the simulator may be traced for an input variable that passes through power generation component 540 to determine that the same input variable does not get processed by the power flow component 542 or line utilization component 548. This identifies the input variables as non-interacting.

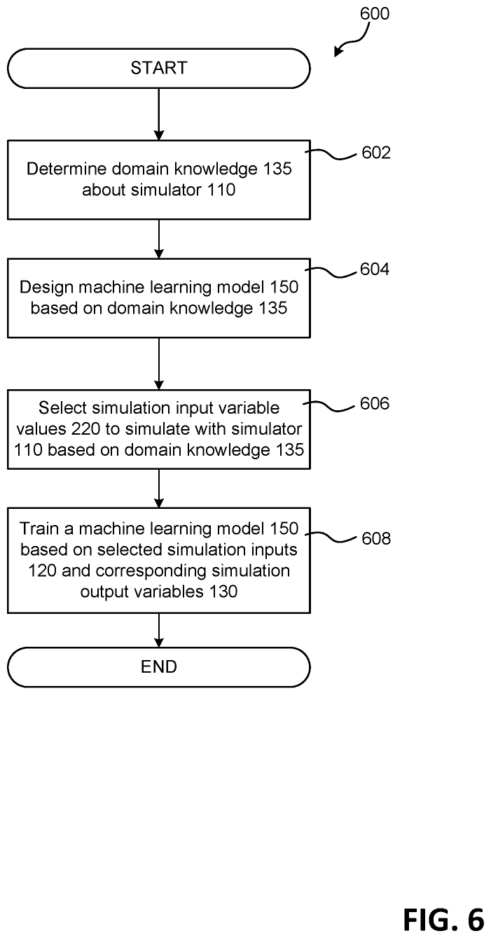

FIG. 6 is a flow diagram illustrating an example operational procedure according to the described implementations.

At operation 602, domain knowledge 135 about simulator 110 is determined.

At operation 604, a machine learning model 150 is designed based on the determined domain knowledge. For example, as discussed above, a larger machine learning model may be replaced by a number of smaller machine learning models that depend on fewer input variables.

At operation 606, input values are selected to be simulated with simulator 110. These inputs and the corresponding outputs generated by the simulator are then provided to the machine learning model builder for processing. In some configurations the values of input variables are selected to be simulated based on domain knowledge. For example, if the structure of the simulator 110 indicates that two variables are non-interacting, then input variable values may be selected so as to adjust one input variable while keeping another input variable constant. This reduces the number of inputs needed to accurately model the behavior of the two inputs by an order of magnitude.

At operation 608, the machine learning model 150 is trained based on the selected simulation input values 220 and corresponding outputs 230.

It should be understood that the operations of the methods disclosed herein are not necessarily presented in any particular order and that performance of some or all of the operations in an alternative order(s) is possible and is contemplated. The operations have been presented in the demonstrated order for ease of description and illustration. Operations may be added, omitted, and/or performed simultaneously, without departing from the scope of the appended claims. It also should be understood that the illustrated methods can be ended at any time and need not be performed in its entirety.

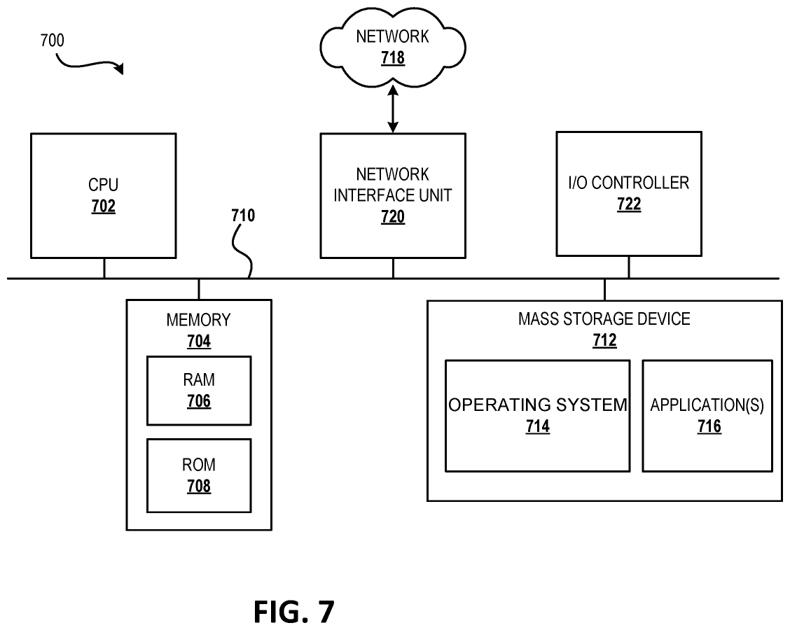

FIG. 7 shows additional details of an example computer architecture 700 for a device, such as simulator 110 or machine learning model trainer 140, capable of executing computer instructions (e.g., a module or a program component described herein). The computer architecture 700 illustrated in FIG. 7 includes processing unit(s) 702, a system memory 704, including a random-access memory 706 (“RAM”) and a read-only memory (“ROM”) 708, and a system bus 710 that couples the memory 704 to the processing unit(s) 702.

Processing unit(s), such as processing unit(s) 702, can represent, for example, a CPU-type processing unit, a GPU-type processing unit, a field-programmable gate array (FPGA), another class of digital signal processor (DSP), or other hardware logic components that may, in some instances, be driven by a CPU. For example, and without limitation, illustrative types of hardware logic components that can be used include Application-Specific Integrated Circuits (ASICs), Application-Specific Standard Products (ASSPs), System-on-a-Chip Systems (SOCs), Complex Programmable Logic Devices (CPLDs), etc.

A basic input/output system containing the basic routines that help to transfer information between elements within the computer architecture 700, such as during startup, is stored in the ROM 708. The computer architecture 700 further includes a mass storage device 712 for storing an operating system 714, application(s) 716 (e.g., simulator 110 or machine learning model trainer 140), and other data described herein.

The mass storage device 712 is connected to processing unit(s) 702 through a mass storage controller connected to the bus 710. The mass storage device 712 and its associated computer-readable media provide non-volatile storage for the computer architecture 700. Although the description of computer-readable media contained herein refers to a mass storage device, it should be appreciated by those skilled in the art that computer-readable media can be any available computer-readable storage media or communication media that can be accessed by the computer architecture 700.

Computer-readable media can include computer-readable storage media and/or communication media. Computer-readable storage media can include one or more of volatile memory, nonvolatile memory, and/or other persistent and/or auxiliary computer storage media, removable and non-removable computer storage media implemented in any method or technology for storage of information such as computer-readable instructions, data structures, program modules, or other data. Thus, computer storage media includes tangible and/or physical forms of media included in a device and/or hardware component that is part of a device or external to a device, including but not limited to random access memory (RAM), static random-access memory (SRAM), dynamic random-access memory (DRAM), phase change memory (PCM), read-only memory (ROM), erasable programmable read-only memory (EPROM), electrically erasable programmable read-only memory (EEPROM), flash memory, compact disc read-only memory (CD-ROM), digital versatile disks (DVDs), optical cards or other optical storage media, magnetic cassettes, magnetic tape, magnetic disk storage, magnetic cards or other magnetic storage devices or media, solid-state memory devices, storage arrays, network attached storage, storage area networks, hosted computer storage or any other storage memory, storage device, and/or storage medium that can be used to store and maintain information for access by a computing device.

In contrast to computer-readable storage media, communication media can embody computer-readable instructions, data structures, program modules, or other data in a modulated data signal, such as a carrier wave, or other transmission mechanism. As defined herein, computer storage media does not include communication media. That is, computer-readable storage media does not include communications media consisting solely of a modulated data signal, a carrier wave, or a propagated signal, per se.

According to various configurations, the computer architecture 700 may operate in a networked environment using logical connections to remote computers through the network 718. The computer architecture 700 may connect to the network 718 through a network interface unit 720 connected to the bus 710. The computer architecture 700 also may include an input/output controller 722 for receiving and processing input from a number of other devices, including a keyboard, mouse, touch, or electronic stylus or pen. Similarly, the input/output controller 722 may provide output to a display screen, speaker, or other type of output device.

It should be appreciated that the software components described herein may, when loaded into the processing unit(s) 702 and executed, transform the processing unit(s) 702 and the overall computer architecture 700 from a general-purpose computing system into a special-purpose computing system customized to facilitate the functionality presented herein. The processing unit(s) 702 may be constructed from any number of transistors or other discrete circuit elements, which may individually or collectively assume any number of states. More specifically, the processing unit(s) 702 may operate as a finite-state machine, in response to executable instructions contained within the software modules disclosed herein. These computer-executable instructions may transform the processing unit(s) 702 by specifying how the processing unit(s) 702 transition between states, thereby transforming the transistors or other discrete hardware elements constituting the processing unit(s) 702.

The present disclosure is supplemented by the following example clauses.

Example 1: A method comprising: determining a domain knowledge of a simulator, wherein the simulator is comprised of a plurality of components; determining a causal relationship between individual input variables of the simulator and individual output variables of the simulator based on the domain knowledge of the simulator; selecting a plurality of input variable values based on the causal relationship; running the simulator with the plurality of input variable values to generate a plurality of output variable values; training a machine learning model with the plurality of input variable values and the corresponding output variable values; and processing an individual set of input variable values with the trained machine learning model to generate a prediction about an aspect of a real-world system simulated by the simulator.

Example 2: The method of example 1, wherein the domain knowledge includes structural knowledge including a listing of the plurality of components, a listing of the plurality of input variables, and a plurality of paths taken by the plurality of input variables through the plurality of components.

Example 3: The method of example 2, wherein the structural knowledge includes a list of intermediate variables that are generated by a first of the plurality of components and that are consumed by a second of the plurality of components.

Example 4: The method of example 1, wherein the causal relationship denotes a conditional non-interacting relationship between the plurality of input variables.

Example 5: The method of example 4, wherein two of the plurality of input variables are determined to be non-interacting based on a determination that an effect of a first of the two input variables on the one or more output variables is independent of a value of the second of the two input variables.

Example 6: The method of example 4, wherein the plurality of input variables are determined to be non-interacting by determining that each of the plurality of input variables affects different, non-overlapping paths through the simulator.

Example 7: The method of example 4, wherein the plurality of input variables are determined to be non-interacting when each of the plurality of input variables are determined to not affect the effect of the remaining input variables of the plurality of input variables.

Example 8: The method of example 7, wherein the plurality of input variables are determined to be non-interacting based on a real-time analysis of the plurality of input variable values and the corresponding plurality of output variable values as the machine learning model is being trained.

Example 9: A computer-readable storage medium storing instructions that, when executed by a processor, cause the processor to: determine a structure of a simulator, wherein the simulator is comprised of a plurality of components; create a design of a machine learning model based on the determined structure of the simulator, wherein the machine learning model accepts a plurality of input variables and produces one or more output variables; determine a causal relationship between the plurality of input variables of the simulator based on the determined structure of the simulator; and replace the machine learning model with a plurality of machine learning models, wherein each of the plurality of machine learning models receives fewer input variables than the machine learning model.

Example 10: The computer-readable storage medium of example 9, wherein determining the causal relationship between the plurality of input variables comprises determining that the plurality of input variables are non-interacting.

Example 11: The computer-readable storage medium of example 10, wherein two of the plurality of input variables are determined to be non-interacting based on a determination that an effect of a first of the two input variables on the one or more output variables is independent of a value of the second of the two input variables.

Example 12: The computer-readable storage medium of example 9, wherein at least two of the plurality of components are modeled with different machine learning models.

Example 13: The computer-readable storage medium of example 9, wherein the instructions further cause the processor to: select a plurality of input variable values based on the causal relationship; run a simulator with the plurality of input variable values to generate a plurality of output variable values; train a machine learning model with the plurality of input variable values and the corresponding output variable values; and process an individual set of input variable values with the trained machine learning model to generate a prediction about an aspect of a real-world system simulated by the simulator

Example 14: The computer-readable storage medium of example 9, wherein the instructions further cause the processor to: derive input values of the trained machine learning model that yield a desired output.

Example 15: A device comprising: one or more processors; and a computer-readable storage medium having encoded thereon computer-executable instructions that cause the one or more processors to: determine a domain knowledge of a simulator, wherein the simulator is comprised of a plurality of components; determine a causal relationship between individual input variables of the simulator and individual output variables of the simulator based on the domain knowledge of the simulator; select a plurality of input variable values based on the causal relationship; run the simulator with the plurality of input variable values to generate a plurality of output variable values; train a machine learning model with the plurality of input variable values and the corresponding output variable values; and process an individual set of input variable values with the trained machine learning model to generate a prediction about an aspect of a real-world system simulated by the simulator.

Example 16: The device of example 15, wherein training the machine learning model with the plurality of input variable values and the corresponding output variable values trains the machine learning model to approximate the simulator.

Example 17: The device of example 15, further comprising: performing an inversion optimization on the machine learning model for a desired output variable value to obtain a set of input variable values that generate the desired output variable value when applied to the machine learning model.

Example 18: The device of example 15, further comprising: refining the machine learning model with data not supplied to or retrieved from the simulator.

Example 19: The device of example 15, wherein the causal relationship comprises a plausible causal relationship that is not disqualified from being a causal relationship but may not be a true causal relationship in the real-world system.

Example 20: The device of example 19, wherein the causal relationship is one of a plurality of plausible causal relationships used to select the plurality of input variables.

The above specification, examples and data provide a complete description of the manufacture and use of the composition of the invention. Since many embodiments of the invention can be made without departing from the spirit and scope of the invention, the invention resides in the claims hereinafter appended.

1. A method comprising:
determining a domain knowledge of a simulator, wherein the simulator is comprised of a plurality of components;
determining a causal relationship between individual input variables of the simulator and individual output variables of the simulator based on the domain knowledge of the simulator;
selecting a plurality of input variable values based on the causal relationship;
running the simulator with the plurality of input variable values to generate a plurality of output variable values;
training a machine learning model with the plurality of input variable values and the corresponding output variable values; and
processing an individual set of input variable values with the trained machine learning model to generate a prediction about an aspect of a real-world system simulated by the simulator.

2. The method of claim 1, wherein the domain knowledge includes structural knowledge including a listing of the plurality of components, a listing of the plurality of input variables, and a plurality of paths taken by the plurality of input variables through the plurality of components.

3. The method of claim 2, wherein the structural knowledge includes a list of intermediate variables that are generated by a first of the plurality of components and that are consumed by a second of the plurality of components.

4. The method of claim 1, wherein the causal relationship denotes a conditional non-interacting relationship between the plurality of input variables.

5. The method of claim 1, further comprising:
optimizing values of the plurality of input variables for a desired set of output variable values.

6. The method of claim 4, wherein the plurality of input variables are determined to be non-interacting by determining that each of the plurality of input variables affects different, non-overlapping paths through the simulator.

7. The method of claim 4, wherein the plurality of input variables are determined to be non-interacting when each of the plurality of input variables are determined to not affect the effect of the remaining input variables of the plurality of input variables.

8. The method of claim 7, wherein the plurality of input variables are determined to be non-interacting based on an analysis of the plurality of input variable values and the corresponding plurality of output variable values as the machine learning model is being trained.

9. A computer-readable storage medium storing instructions that, when executed by a processor, cause the processor to:
determine a structure of a simulator, wherein the simulator is comprised of a plurality of components;
create a design of a machine learning model based on the determined structure of the simulator, wherein the machine learning model accepts a plurality of input variables and produces one or more output variables;
determine a causal relationship between the plurality of input variables of the simulator based on the determined structure of the simulator; and
replace the machine learning model with a plurality of machine learning models, wherein each of the plurality of machine learning models receives fewer input variables than the machine learning model.

10. The computer-readable storage medium of claim 9, wherein determining the causal relationship between the plurality of input variables comprises determining that the plurality of input variables are non-interacting.

11. The computer-readable storage medium of claim 10, wherein two of the plurality of input variables are determined to be non-interacting based on a determination that an effect of a first of the two input variables on the one or more output variables is independent of a value of the second of the two input variables.

12. The computer-readable storage medium of claim 9, wherein at least two of the plurality of components are modeled with different machine learning models.

13. The computer-readable storage medium of claim 9, wherein the instructions further cause the processor to:
select a plurality of input variable values based on the causal relationship;
run a simulator with the plurality of input variable values to generate a plurality of output variable values;
train a machine learning model with the plurality of input variable values and the corresponding output variable values; and
process an individual set of input variable values with the trained machine learning model to generate a prediction about an aspect of a real-world system simulated by the simulator

14. The computer-readable storage medium of claim 9, wherein the instructions further cause the processor to:
derive input values of the trained machine learning model that yield a desired output value.

15. A device comprising:
one or more processors; and
a computer-readable storage medium having encoded thereon computer-executable instructions that cause the one or more processors to:
determine a domain knowledge of a simulator, wherein the simulator is comprised of a plurality of components;
determine a causal relationship between individual input variables of the simulator and individual output variables of the simulator based on the domain knowledge of the simulator;
select a plurality of input variable values based on the causal relationship;
run the simulator with the plurality of input variable values to generate a plurality of output variable values;
train a machine learning model with the plurality of input variable values and the corresponding output variable values; and
process an individual set of input variable values with the trained machine learning model to generate a prediction about an aspect of a real-world system simulated by the simulator.

16. The device of claim 15, wherein training the machine learning model with the plurality of input variable values and the corresponding output variable values trains the machine learning model to approximate the simulator.

17. The device of claim 15, further comprising:
performing an inversion optimization on the machine learning model for a desired output variable value to obtain a set of input variable values that generate the desired output variable value when applied to the machine learning model.

18. The device of claim 15, further comprising:
refining the machine learning model with data not supplied to or retrieved from the simulator.

19. The device of claim 15, wherein the causal relationship comprises a plausible causal relationship that is not disqualified from being a causal relationship but may not be a true causal relationship in the real-world system.

20. The device of claim 19, wherein the causal relationship is one of a plurality of plausible causal relationships used to select the plurality of input variables.
